(19) United States
(12) Patent Application Publication
(10) Pub. No.: US 2009/0020416 A1
(43) Pub. Date: Jan. 22, 2009

(54) SPUTTER COATING DEVICE AND METHOD OF DEPOSITING A LAYER ON A SUBSTRATE

(75) Inventors: James Scholhammer, Pleasanton, CA (US); Uwe Hoffmann, Alzenau (DE); Jose Manuel Dieguez-Campo, Hanau (DE)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 12/145,755

(22) Filed: Jun. 25, 2008

Related U.S. Application Data
(60) Provisional application No. 60/950,515, filed on Jul. 18, 2007.

(30) Foreign Application Priority Data
Jul. 18, 2007 (EP) EP07112691.6

(51) Int. Cl. C23C 14/35

(52) U.S. Cl. 204/192.12; 204/298.11

(57) ABSTRACT

A sputter coating device comprises a vacuum coating chamber, substrates arranged within the coating chamber, a cylindrical hollow cathode including a rotatable target rotating around a central axis A, and a magnet assembly which is arranged within the hollow cathode such that confining plasma zones are generated in an area above the surface of the target. At least one substrate is to be coated. The substrate has an OLED layer deposited on the substrate surface. An intermediate area is arranged between the surface of the target and a shield that shields particles sputtered from the surface of the target that move in a direction toward the shield. On each side of the shield, passages are provided between the intermediate area and coating area. Through the passage, only sputtered particles that have been scattered in the intermediate area may enter the coating area via the passage, and impinge the OLED layer.

### CROSS-REFERENCES TO RELATED APPLICATIONS

This nonprovisonal application claims the benefit of the filing date of, U.S. Prov. Pat. Appl. No. 60/950,515, entitled “SPUTTER COATING DEVICE AND METHOD OF DEPOSITING A LAYER ON A SUBSTRATE,” filed Jul. 18, 2007, the entire disclosure of which is incorporated herein by reference for all purposes. This nonprovisonal application also claims the benefit of the European Patent No. EP07112691.6, entitled “SPUTTER COATING DEVICE AND METHOD OF DEPOSITING A LAYER ON A SUBSTRATE,” filed Jul. 18, 2007, the entire disclosure of which is incorporated herein by reference for all purposes.

### BACKGROUND OF THE INVENTION

This application relates to a sputter coating device for depositing a layer on a substrate having an organic material layer deposited thereon. Furthermore, this application relates to a method of depositing a layer on a substrate having an organic material layer deposited thereon.

In many applications, organic material layers, such as organic electronics, organic light emitting devices (OLEDs), are part of a layer stack. Usually, organic material layers are functional layers that require a metallization layer, a contact layer or a protective layer deposited directly or indirectly on the organic material layer.

A conventional process used for coating organic material layers, e.g. OLED layers, with a protective or metallization layer without damaging the organic material layer, is an evaporation of coating particles on top of the organic material layers. In the evaporation process, a metal source may be used. Furthermore, special processing conditions may be provided like particular OLED layer stacks including protection layers.

Another approach is to use standard sputter processes like magnetron sputtering. However, it has been discovered that the underlying organic layers is considerably damaged when using conventional sputtering. Therefore, in order to provide a softer sputtering process, a face-to-face sputter concept has been introduced thereby reducing risk of damaging the organic layer. This may be due to a reduced velocity of the particles impinging the organic layer. This technology has, for example, been described in European Patent EP1505170 B1, the entire content of which is incorporated herein by reference for all purposes.

FIG. 1 illustrates a conventional face-to-face sputtering apparatus 1 comprising a first target 2 and a second target 3. The first sputter surface 2′ of the first target 2 and the second sputter surface 3′ of the second target 3 are arranged such as to face each other.

The first target 2 comprises a first magnet assembly 4 to generate at least one plasma generation (or plasma confinement) zone 6 above the surface 2′ of the first target 2. The second target 3 comprises a second magnet assembly 5 for generating at least a second plasma generation (or plasma confinement) zone 7 above the surface 3′ of the second target 3. Within the plasma zones 6 and 7, ions are generated for sputtering coating particles or reaction particles from the target surfaces 2′ and 3′, respectively. The prevailing direction of the movement of the sputtered particles is directed toward the opposite surface 3′ and 2′, respectively, of the opposing target 3 and 2, respectively.

A number of sputtered particles may be scattered in the intermediate zone 8 between the target surfaces 2′ and 3′, and may enter a coating zone 13 via a path 12. The scattered particles have lost enough kinetic energy while being scattered to reduce damage to an organic layer 11 when impinging a substrate 10.

However, there are some disadvantages when using the above processes. First, the coating yield may be very low and thus the throughput of the substrates may be unsatisfactory. Furthermore, particularly when coating with reactive particles such as Al, the use of conventional face-to-face sputter arrangements may result in re-deposition of coating material from one magnetron to the other. In reactive processes like sputtering of Indium Tin Oxide (ITO), this re-deposition may result in poisoning of the targets involved in the coating process. Even for non-reactive processes like sputtering of Al, this re-deposition may result in the formation of a layer re-deposition area of the target where no sputtering occurs. This may cause shorts at the target or, the particles may reach the substrate to destroy the substrate.

### BRIEF SUMMARY OF THE INVENTION

It is an object of the present invention to provide a device and a process for damage free or damage-reduced sputter coating on top of an organic material layer, e.g. on top of an OLED layer, the process having an acceptable coating rate.

This object is solved by providing a sputter coating device and a method of depositing a layer on a substrate.

A sputter coating device according to the invention for depositing a layer on a substrate having an organic material layer deposited thereon, comprises: a coating chamber; a substrate having an organic material layer deposited thereon; at least a rotatable cathode unit arranged in the coating chamber comprising at least one rotatable target and a magnet assembly for generating at lease one plasma confinement zone arranged above at least a surface section of the target; a scattering zone for scattering sputtered particles, and means for selectively preventing a portion of the sputtered particles from directly moving to the surface of the substrate.

The means prevents a ratio of sputtered particles from moving from the surface section of the target to the surface of the substrate on a direct path, i.e., without being scattered. This direct path would usually be a substantially linear path. The scattering zone is located on the path of particles between the target surface and the substrate surface. The term scattering zone may be interpreted in a broad sense, including, e.g., a deflection or reflection of particles resulting in a loss of kinetic energy and/or a change of the direction of movement of the particles. Particles in the sense of the invention are particles sputtered from the target, i.e., atoms, ions, radicals, molecules, but not mote-like particles flaking off the target surface.

The means acts as kind of a filter that filters particles from a stream of sputtered particles, especially the particles that have not been scattered in the scattering zone, thus allowing only scattered particles to impinge on the substrate surface.

Particularly, the means comprises an arrangement and/or configuration of the surface section, the scattering zone, and the substrate surface such that at least a portion of the sputtered particles scattered in the scattering zone passes the means to impinge the substrate surface.

In a specific embodiment, the means comprises at least one passage between the scattering zone and the at least one substrate, wherein the passage is arranged and/or configured for allowing selective passage of particles scattered in the scattering zone to the at least one substrate.

The sputter coating device is particularly used for depositing a thin film, e.g. a protective film, a metallization and/or electrode layer, e.g. an Al layer, a TCO (transparent conducting oxides) layer such as ITO (indium tin oxide), etc., on an organic material layer. An organic material layer is a layer that comprises at least an organic material, such as an organic electronics layer or an OLED (Organic Light Emitting Device) layer. The film may be deposited directly on the underlying organic material layer or indirectly, i.e. on top of one or more layers deposited on the organic material layer. For example, in some applications, a thin layer of LiF or other materials is deposited on the organic material layer before the thin film according to the present invention is deposited. Due to the high reactivity of oxygen radicals, particularly the deposition of TCO layers entails major difficulties and problems like poisoning of the targets.

An important feature of the present invention is that at least one rotatable cathode unit is used. The power of the cathode may be DC, RF, mixtures of DC and RF, or pulse modulated power. A rotatable cathode comprises a cylindrical hollow target having a magnet assembly (magnetron), a cooling system, etc., arranged therein. The particular aspect of using rotatable cathodes in the arrangement according to the present invention is, e.g., a reduction of poisoning of a second target that may be involved in the coating process, in the case of reactive processes. Furthermore, shields may be provided, and may be exchanged so easily that a simple maintenance of the coating device is facilitated. Moreover, rotatable targets may have a higher yield and better material utilization because of the uniform erosion of the targets as a result of rotation of the targets.

In order to prevent damage caused by direct particles impinging the organic material layer or a thin layer deposited on the organic material layer, the present invention uses an arrangement having rotatable cathodes with a magnet system facing away from the substrate surface. This results in coating conditions where only scattered particles impinge the substrate surface. Particles that are not scattered may be captured on a shield.

The deposition of the layer on top of the organic material layer (or a thin layer deposited thereon) may be provided in a static coating or in a dynamic coating process. In the static coating process, the substrate is fixedly arranged within the vacuum coating chamber during the coating process. In the dynamic coating process, the substrate is moved relative to the cathode while being coated. The rotatable target rotates around an axis and moves relative to a fixed magnet assembly. The magnet assembly generates a plasma confinement zone. In magnetron plasma sputtering processes, the coating and/or the reactive particles in case of a reactive sputtering are essentially sputtered from a surface section of the target surface which is near or adjacent to the plasma confinement zone.

The target surface sections near the plasma confinement zones are arranged in one or more perimeter sections of the target surface. The perimeter sections of the target surface are not arranged opposite the substrate surface like in a conventional sputter process. Particularly, the magnet assembly may comprise magnet bars extending parallel to the rotational axis of the target. The magnet bars are not arranged near a connecting line between the rotational axis and the substrate surface, but facing away from the substrate surface. For example, the magnet bars may be arranged in an angle of about 90° relative to the normal vector of the substrate area. This arrangement ensures that very few sputter particles may reach the substrate surface on a direct path when moving away from the target surface without any collisions. Scattered particles, on the other hand, may reach the substrate surface. Due to the collision(s), the energy of the coating particles impinging the organic material layer (or a thin film deposited thereon) is reduced to result in a lower risk of damaging the organic material layer.

Particularly, the means for preventing sputtered particles from moving from the surface section of the target to the surface of the substrate to be coated directly on a substantially linear path comprises a configuration and/or an arrangement of the magnet assembly such that the average prevailing direction of movement of sputtered particles near the surface of the target is not directed toward the substrate surface.

According to the present invention, a direct movement of sputtered particles toward and onto the organic material layer is not desirable due to the ability of these particles having a high impulse to damage the organic material layer. Even if the organic material layer is provided with a thin film on top thereof, the organic material layer is not protected sufficiently from directly sputtered particles. Therefore, the magnet assembly is arranged in a direction that does not face the substrate surface, but rather is turned away (e.g., in an angle of 90°) from the substrate surface. Thus, the prevailing average direction of movement of particles sputtered from the target surface (before the particles may be scattered) is directed away from the substrate surface. There is no direct movement on a linear path, i.e., no movement free of collisions between the target surface section and the substrate surface. Only scattered particles that have lost kinetic energy due to collisions with other particles, impinge the organic layer without causing damage to the organic layer. In this way, a damage free or damage reduced sputtering process on organic material layers, e.g., OLED layers, using rotatable cathode technology, is provided.

Even if directly sputtered particles may possibly reach the surface, this case is still within the scope of the present invention as long as the number of the directly sputtered particles has been reduced compared to the number of scattered particles impinging the organic material layer.

In one embodiment, the means is configured such that there is a connecting path between the target surface and the substrate surface to be coated for particles sputtered from the target surface and scattered in an area above the target surface. In other words, there is a path providing an indirect connection between the target surface and the substrate surface such that only scattered particles may reach the substrate surface.

The means may particularly comprise at least one shield for preventing particles sputtered from the target to impinge the substrate surface directly on a linear path.

It should be ensured that at least the majority of particles reaching the substrate surface were scattered during traveling from the target surface to the substrate surface. Additional shields having openings may be particularly designed to optimize the number of scattered particles reaching the substrate surface and thus increasing the coating rate/yield. On the other hand, the number of particles impinging the substrate surface without being scattered on the way from the target surface to the substrate surface must be reduced.

The sputter coating device may comprise at least a first rotatable cathode unit arranged in the coating chamber comprising at least a first rotatable target and a first magnet assembly for generating at least a first plasma confinement zone arranged above at least a first surface section of the first target, and at least a second cathode unit arranged in the coating chamber comprising at least a second target and a second magnet assembly for generating at least a second plasma confinement zone arranged above at least a second surface section of the second target, wherein the means are configured to prevent sputtered particles from moving from the first target surface and the second target surface to the substrate surface on a substantially linear path. The second cathode unit may be a flat or a rotatable cathode unit having a flat and rotatable target, respectively.

The power of cathodes can be DC, RF, mixtures of DC and RF, or pulse modulated power. The two rotatable cathodes may also be used in a twin-mag mode. It is desirable that the main direction of the deposition is toward the other rotatable cathode.

In another embodiment, the means comprises a configuration and/or arrangement of the first magnet assembly and the second magnet assembly such that the first surface section of the first target surface, and the second surface section of the second target surface are arranged face-to-face defining an intermediate zone there between.

The coating device of this embodiment comprises an arrangement of two targets with a magnet assembly attributed to each of the targets. The targets are particularly arranged in a face-to-face arrangement defining an intermediate zone between the targets. In this intermediate zone, a high density of particles may be generated, thus increasing the probability of scattering of the particles and the rate of coating of the substrate with scattered particles. Furthermore, poisoning may be reduced in reactive processes, e.g., when coating with TCO, as rotatable targets are less susceptible for poisoning. In addition, when using a rotatable target, the re-deposition zone is reduced to a minimum (at both ends of the target) because each portion of the target surface passes the sputtering area as the target rotates.

The sputter coating device may comprise at least one shield between the intermediate zone and the substrate surface, the shield having at least one opening for scattered particles to move toward the substrate surface.

The object of the invention is also solved by providing a method of depositing a layer on a substrate having an organic material layer deposited thereon, the method comprising the steps of:
a) Providing a coating chamber;
b) Providing a substrate to be coated in the coating chamber having at least an organic material layer deposited thereon;
c) Providing at least one rotatable cathode unit arranged in the coating chamber comprising at least a rotatable target and a magnet assembly for generating at least one plasma confinement zone arranged above at least a surface section of the target;
d) Providing means for preventing sputtered particles from moving from the target surface to the substrate surface on a substantially direct path; and
e) Sputtering particles from the rotatable target.

Step d) may include providing a scattering zone for sputtered particles. When being scattered, the particles lose kinetic energy and/or change their directions of movement. Due to the different directions of movement of scattered and non-scattered particles, the non-scattered particles may be filtered from the stream of all particles reaching the scattering zone. The particles moving without having been scattered may be deposited on a shield. A portion of the scattered particles moves in a direction toward the substrate surface.

Particularly, step c) includes arranging the magnet assembly such that the average prevailing direction of movement of sputtered particles near the surface of the target is not directed toward the substrate surface.

In a specific embodiment, step d) includes providing a connecting path between the surface section of the target and the substrate surface to be coated for particles sputtered from the target surface and scattered in the scattering zone.

Step d) may include providing at least one shield between the scattering zone and the substrate surface.

Particularly, step c) includes providing a first rotatable cathode unit arranged in the coating chamber comprising at least a first rotatable target and a first magnet assembly for generating at least a first plasma confinement zone arranged above at least a first surface section of the target, and at least a second cathode unit arranged in the coating chamber comprising at least a second target and a second magnet assembly for generating at least a second plasma confinement zone arranged above at least a second surface section of the second target. The second target may be a flat target or a rotatable target.

Step c) may include arranging the first magnet assembly and the second magnet assembly such that particles sputtered from the first target surface and the second target surface have a prevailing direction of movement toward the second target surface and the first target surface, respectively. This arrangement corresponds to a face-to-face arrangement of the magnet assemblies.

Particularly, step d) includes providing at least a shield having an opening for allowing scattered particles sputtered from aid at least one target to pass through the opening and to impinge the substrate surface to be coated.

During step d) the substrate surface may be arranged substantially parallel relative to an average prevailing direction of movement of the sputtered particles near the target surface.

In an alternative embodiment, the method after depositing the layer on the organic material layer deposited on the substrate may further include the following step f): sputtering particles from a rotatable target such that the sputtered particles have an average prevailing direction of movement toward the substrate surface to be coated to allow the particles to impinge the substrate surface directly on a linear path.

In this embodiment, according to the basic method described above, a first thin layer, i.e., a sublayer, is deposited on the organic material layer. The sublayer may protect the organic material layer from the influence of impinging sputtered particles having a high kinetic energy. During step f) that refers to the formation of a second thick layer on the sublayer by direct sputtering, the second thick layer may be coated in one or more additional cathodes, which may be planar or rotatable cathodes. The second layer may be of the same or similar material as the first layer, e.g., a metal material such as Al.

Particularly, step f) includes changing, after a first layer has been deposited on the substrate surface, the alignment of the magnet assembly from a direction not facing the substrate surface to a direction facing the substrate surface, and depositing a second layer on the first layer. In other words, the sputter direction is changed, for example, by rotating the magnet system relative to the substrate in a direction toward the substrate. The second layer may be coated with the same rotatable cathode as the first layer by moving the magnet bar of the magnetron toward the substrate and therefore the main deposition direction directed toward the substrate. Of course, there is also the possibility to move the substrate from a position where the substrate surface does not face the magnet assembly to a position, where the substrate surface faces the magnet assembly.

Step f) may include transporting the substrate from a first rotatable target to a second rotatable target, and then sputtering particles from the second rotatable target to deposit a second layer on the first layer.

The first layer deposited during step e) may have a thickness between 5 nm and 100 nm, and/or the second layer deposited in step f) may have a thickness between 10 nm and 1000 nm.

### BRIEF DESCRIPTION OF THE DRAWINGS

A further understanding of the nature and advantages may result from the remaining portions of the specification and the drawings.

FIG. 1 depicts a conventional face-to-face target sputtering apparatus.

FIG. 2 shows a first coating device of the present invention.

FIG. 3 is a second coating device of the present invention.

FIG. 4A illustrates an operation of a first coating device for depositing a thin layer on top of an OLED layer according to the present invention.

FIG. 4B illustrates an operation mode of a second coating device for depositing a thick layer on top of the thin layer shown in FIG. 4A according to the present invention.

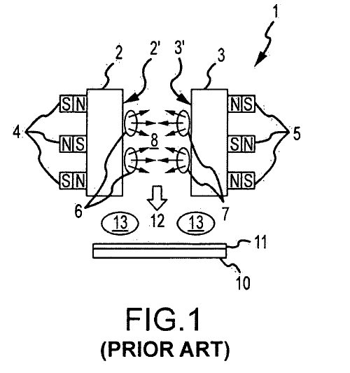

### DETAILED DESCRIPTION OF THE INVENTION

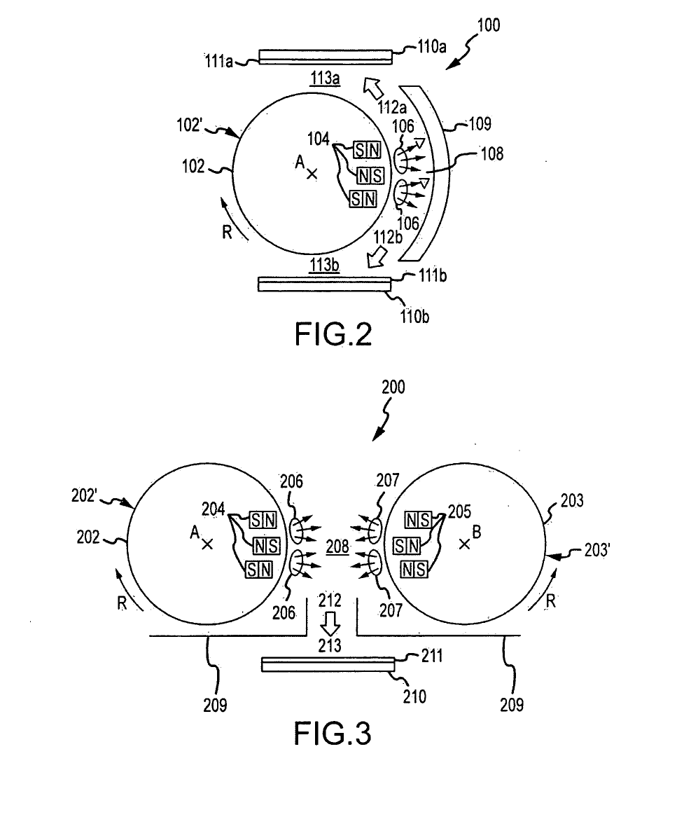

FIG. 2 illustrates a first embodiment of a sputter coating device 100 according to the present invention. The sputter coating device 100 comprises a vacuum coating chamber (not illustrated), and substrates 110a and 110b arranged within the coating chamber. Furthermore, the sputter coating device 100 comprises a cylindrical hollow cathode including a rotatable target 102 rotating around a central axis A, and a magnet assembly 104 which is arranged within the hollow cathode and arranged such that confining plasma zones 106 are generated in an area 108 above the surface 102′ of the target 102. The area 108 is arranged such that the prevailing direction of movement of particles sputtered from the surface 102′ of the target 102 is not directed toward the substrate surface to be coated.

In this embodiment, there are two substrates 110a and 110b to be coated at the same time. Both substrates have an OLED layer 111a and 111b, respectively, deposited on the substrate surface. However, it is also possible to have only one substrate located near the particle source/scattered area/intermediate area (defined by the target surface 102′ and the shield 109) 108 in order to be coated. The coating may be provided on the organic layer 111a, 111b or on a thin film deposited therein, e.g., a LiF film.

The scattered area 108 is arranged between the target surface 102′ and a shield 109 which shields particles sputtered from the surface 102′ of the target 102 that move in a direction toward the shield 109. On each side of the shield 109 passages 112a and 112b (indicated by arrows) are provided between the intermediate area 108 (defined by the target surface 102′ and the shield 109) and the coating areas 113a, 113b. Through these passages 112a and 112b, only sputtered coating particles which have been scattered in the intermediate area 108 may enter coating area 113a, 113b, respectively, and impinge the OLED layers 111a or 111b or thin films deposited thereon. Of course, it cannot be prevented that sputter gases like Argon, Oxygen (when sputtering TCOs), etc. also pass the passages 112a and 112b. However, it is intended to reduce the number of particles sputtered from the target to impinge the substrate surface without having been scattered in the scattering zone 108.

In a static coating process, the substrates 110a and 110b are immovable during the coating process, while in a dynamic coating process, the substrates 110a and 110b may be moved relative to the sputter coating device 100 in the coating chamber. When passing the sputter coating device, electrode layers are formed on top of the OLED layers 111a and 111b deposited on the substrates 110a and 110b, respectively.

Furthermore, a shield 109 is provided to shield particles sputtered from the surface 102′ of the target 102 that move in a direction toward the shield 109. On each side of the shield 109, passages 112a and 112b (indicated by arrows) are provided between the intermediate area 108 (defined by the target surface 102′ and the shield 109) and the coating areas 113a, 113b. Through these passages 112a and 112b, only sputtered particles which have been scattered in the intermediate area 108 may enter coating areas 113a, 113b via paths 112a and 112b, respectively, and impinge the OLED layers 111a or 111b.

FIG. 3 is an illustration of a second embodiment of the inventive sputter coating device 200. The second sputter coating device 200 comprises a vacuum coating chamber (not illustrated), a first rotatable cathode having a first target 202, and a second rotatable cathode having a second target 203. The targets 202 and 203 are rotatable around central axes A and B, respectively. Furthermore, the first and second cathodes 202 and 203 comprise a magnet assembly 204 and 205, respectively. The magnets 204 and 205 are arranged such that two plasma confinement zones 206 and 207 are generated in a defined area between the targets 202 and 203.

The plasma confinement zones 206 and 207 are positioned in an intermediate space 208 between the targets 202 an 203. The particles sputtered from the target surfaces 202′ and 203′ in an area near the plasma confinement zones 206 and 207 have a prevailing direction of movement toward the other rotatable cathodes 203 and 202, respectively. The magnet assemblies, 204, 205 are arranged face-to-face.

Furthermore, the sputter coating device 200 may comprise a shield 209 having an opening 212 between the intermediate area 208 where a certain fraction of sputtered particles are scattered and enter a coating area 213 via the opening 212. The scattered particles have a relatively low kinetic energy when impinging the OLED layer 211 on the substrate 210 because of lost kinetic energy during the collision(s) with other particles. However, in some applications, shield 209 may not be required if the number of non-scattered particles impinging the substrate surface can be sufficiently reduced without a shield.

The advantage of the described coating devices 100 and 200 is that the majority of particles has been scattered when entering the coating areas 213, 113a or 113b. Consequently, a coating is provided with particles of reduced energy due to scattering when using the coating devices 100, 200 according to the invention. Thus, the coating process does not cause damage to the organic layer 111.

By using one or more rotatable cathodes, a uniform erosion of material from the target surfaces 202′, 203′, 102′ may be obtained. For example, when using flat targets, certain areas of the target surface are not sputtered. In a face-to-face arrangement, particles from the other cathode may be deposited in these areas causing spurious effects.

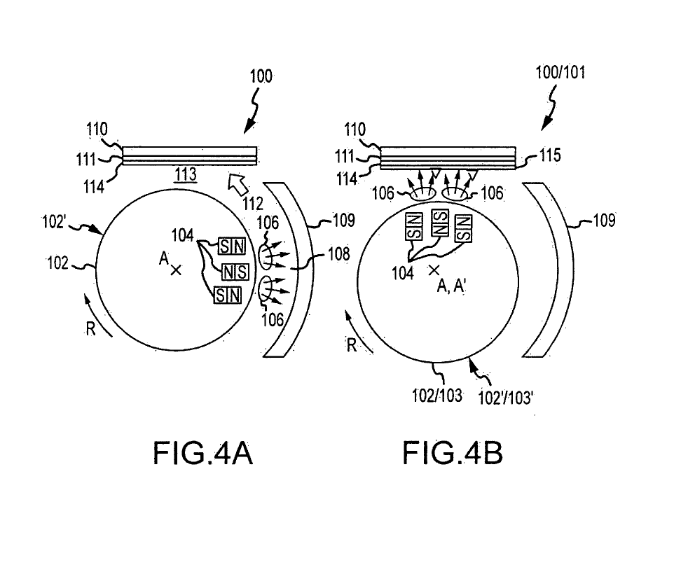

FIG. 4A illustrates an operation mode of a first sputter coating device 100 for depositing a thin layer on top of an OLED layer according to the invention. FIG. 4B illustrates an operation mode of the first coating device 100 or a different coating device 101 for depositing a thick layer on top of the thin layer shown in FIG. 4A.

In FIG. 4A, corresponding to a first coating process, there is a sputter coating device 100 as shown in FIG. 2. In the first coating process, a substrate 110 having an OLED layer 111 deposited therein is coated with a first sublayer, e.g., a metal layer 114. During the sputter coating process, the rotatable target 102 rotates around a central axis A. The sputter coating device 100 comprises a magnet assembly 104 which is arranged in the interior of the cylindrical hollow cathode 102 on a side not facing the surface of the substrate 110. Only particles scattered in the intermediate zone 108 may enter the coating area 113 and impinge on the OLED layer 113. These particles form a thin electrode layer 114 on the organic layer 111, e.g., a thin metal layer 114 having a thickness d between 5 nm and 100 nm. The remaining particles (not scattered or scattered in another direction) are stopped by a shield 109.

In a second coating process (illustrated in FIG. 4B) which may be performed in the same sputter coating device 100 or in a different sputter coating device 101, a second thick layer 115 is deposited on the first thin layer 114 formed in the described first step on top of the organic layer 111. The coating device 101 comprises a vacuum coating chamber (not illustrated) and a cathode having a rotatable target.

The second thick layer 115 may be formed with the magnet assembly 104 of the rotatable cathode directed toward the surface of the substrate 110 and the first metal thin layer 114. In this configuration, the majority of particles sputtered from the target surface 102′ near the plasma confinement zones 106 move directly to the substrate surface and impinge the thin layer 114 with a relatively high kinetic energy. However, the particles do not impinge the organic layer 111 which is covered and protected by the thin layer 114. Therefore, the particles forming the second thick layer 115 do not damage the OLED layer 111.

The second thick layer 115 having a thickness d between 10 nm and 1000 nm may thus be produced with a significantly higher deposition rate. Only the thin layer 114 must be deposited with a lower deposition rate in the first step than the second step. The thin layer 114 and the thick layer 115 deposited thereon may consist of the same or a similar material.

The second process may be performed after transporting the substrate 110 coated with an organic layer 111, or an OLED layer 111, and a thin electrode layer 114 to the sputter coating device 101 in order to deposit the second thick electrode layer 115.

Alternatively, the same sputter coating device 100 may be used for performing the second coating process with the magnet assembly 104 turned by 90° in a direction directly facing the surface to be coated. In this alternative embodiment, the same cathode may be used for both processes.

Thus, having described several embodiments, it will be recognized by those of skill in the art that various modifications, alternative constructions, and equivalents may be used without departing from the spirit of the invention. Accordingly, the above description should not be taken as limiting the scope of the invention, which is defined in the following claims.

What is claimed is:

1. A sputter coating device for depositing a layer on a substrate having an organic material layer deposited thereon, the sputter coating device comprising:
a coating chamber;
a substrate having a surface and an organic material layer deposited thereon;
a rotatable cathode unit arranged in the coating chamber comprising a rotatable target for sputtering particles from the target and a magnet assembly for generating a plasma confinement zone arranged above a surface section of the target;
a scattering zone provided between the surface section of the target and the substrate surface for scattering the sputtered particles; and
means for selectively preventing a portion of the sputtered particles from moving to the substrate surface.

2. The sputter coating device according to claim 1, wherein the means comprises an arrangement and/or configuration of the surface section of the target, the scattering zone and the substrate surface such that the portion of the sputtered particles scattered in the scattering zone passes the means to impinge the substrate surface.

3. The sputter coating device according to claim 1, wherein the means comprises a passage between the scattering zone and the substrate wherein the passage is arranged and/or configured for a selective passage of particles scattered in the scattering zone to the substrate surface.

4. The sputter coating device according to claim 1, wherein the means comprises a configuration and/or an arrangement of the magnet assembly such that the average prevailing direction of movement of sputtered particles near the surface of the target is not directed toward the substrate surface.

5. The sputter coating device according to claim 1, wherein the means is configured such that there is a connecting path between the surface section of the target and the substrate surface to be coated for particles sputtered from the surface of the target and scattered in a defined area.

6. The sputter coating device according to claim 1, wherein the means comprises at least one shield.

7. The sputter coating device according to claim 1, wherein the sputter coating device comprises:
a first rotatable cathode unit arranged in the coating chamber comprising a first rotatable target and a first magnet assembly for generating a first plasma confinement zone arranged above a first surface section of the first target; and
a second rotatable cathode unit arranged in the coating chamber comprising a second target and a second magnet assembly for generating a second plasma confinement zone arranged above a surface section of the second target,
wherein the means are configured to selectively prevent the portion of the sputtered particles from moving to the surface of the substrate.

8. The sputter coating device according to claim 7, wherein the means comprises a configuration and/or arrangement of the first magnet assembly and the second magnet assembly such that the first surface section of the first target surface, and the second surface section of the second target surface are arranged face-to-face defining an intermediate zone there between.

9. The sputter coating device according to claim 8, wherein the sputter coating device comprises at least one shield between the intermediate zone and the substrate surface, the shield having at least one opening for scattered particles to move toward the substrate surface.

10. A method of depositing a layer on a substrate having an organic material layer deposited thereon, the method comprising the steps of:
a. Providing a first coating chamber;
b. Providing a substrate to be coated in the first coating chamber, the substrate having an organic material layer deposited thereon;
c. Providing a first rotatable cathode unit arranged in the first coating chamber comprising a first rotatable target and a first magnet assembly for generating a first plasma confinement zone arranged above a surface section of the first target;
d. Providing means for preventing sputtered particles from moving from the surface of the first rotatable target to the substrate surface on a substantially direct path; and
e. Sputtering particles from the first rotatable target to form a first layer on the substrate.

11. The method according to claim 10, wherein step c) comprises arranging the magnet assembly such that the average prevailing direction of movement of sputtered particles near the surface of the target is not directed toward the substrate surface.

12. The method according to 10, wherein the step c) comprises providing a second rotatable cathode unit arranged in the first coating chamber, the second cathode unit comprising a second rotatable target and a second magnet assembly for generating a second plasma confinement zone arranged above a surface section of the second target.

13. The method according to claim 12, wherein step c) comprises arranging the first magnet assembly and the second magnet assembly, wherein particles sputtered from the surface of the first target have a prevailing direction of movement toward the surface of the second target, wherein particles sputtered from the surface of the second target have a prevailing direction of movement toward the surface of the first target surface.

14. The method according to claim 10, wherein step d) comprises providing a connecting path between the surface section of the target and the substrate surface to be coated for particles sputtered from the surface of the target and scattered in a scattering zone.

15. The method according to claim 14, wherein step d) comprises providing at least one shield between the scattering zone and the substrate surface.

16. The method according to claim 14, wherein step d) comprises providing at least one shield having an opening for allowing the scattered particles sputtered from the target to pass through the opening and to impinge the substrate surface to be coated.

17. The method according to claim 10, wherein during the step e) the substrate surface is arranged substantially parallel relative to an average prevailing direction of movement of the sputtered particles near the surface of the target.

18. The method according to claim 10, the method further comprising step f) after depositing the first layer on the substrate:
f) Sputtering particles from a second rotatable target in a second coating chamber such that the sputtered particles have an average prevailing direction of movement toward the substrate surface to be coated for allowing the particles to impinge the substrate surface directly.

19. The method according to claim 18, wherein step f) comprises changing the alignment of the magnet assembly from a direction not facing the substrate surface to a direction facing the substrate surface.

20. The method according to claim 18, wherein step f) comprises:
transporting the substrate from the first coating chamber to the second coating chamber; and
sputtering particles from the second rotatable target to deposit a second layer on the first layer.

21. The method according to previous claims 20, wherein the first layer deposited during step e) comprises a thickness between 5 nm and 100 nm, wherein the second layer deposited in step f) comprises a thickness between 10 nm and 1000 nm.
